(19) United States
(12) Patent Application Publication
(10) Pub. No.: US 2002/0121943 A1
(43) Pub. Date: Sep. 5, 2002

(54) EMI filters based on amorphous metals in a form of a microwire, a ribbon and/or a powder

(76) Inventors: Alexander Axelrod, Moshav Haniel (IL); Vladimir Manov, Haifa (IL); Eugeni Sorkine, Tel Aviv (IL)

Correspondence Address: DR. MARK FRIEDMAN LTD., c/o BILL POLKINGHORN - DISCOVERY DISPATCH, 9003 FLORIN WAY, UPPER MARLBORO, MD, 20772, US

(21) Appl. No.: 09/753,488

(22) Filed: Jan. 4, 2001

Related U.S. Application Data
(60) Provisional application No. 60/206,805, filed on May 25, 2000.

(51) Int. Cl. H03H 7/01

(52) U.S. Cl. 333/182; 333/185

(57) ABSTRACT

An electro-magnetic interference (EMI) filter assembly comprising of an absorbing layer filled with magnetic material in a form of microwires, metallic ribbons or powder, the magnetic material-filled layer in close proximity to an electrical conductor carrying a common mode noise current superimposed on a functional differential-mode current. The absorbing layer performs the EMI filtering by means of reflection and absorption of high frequency energy of the common mode current due to the high magnetic permeability of the layer's magnetic substance. An appropriate filler compound reinforces the magnetic substance in the magnetic material-filled layer. A circuit laminate which is adjacent to the magnetic material-filled layer supports the electrical conductor(s), to give a basic structure of a PCB filter in which the magnetic material is embedded. Various configurations of the basic filter assembly are described, such as multi-layer filters and optimized transmission lines. Several embodiments of the invention are disclosed in which a PCB magnetic material embedded filter is attached to an host customer PCB or to an electrical connector in order to filter the common mode current especially in the regions near the Input/Output of the host device.

### FIELD AND BACKGROUND OF THE INVENTION

This invention relates generally to filters suitable for eliminating unwanted noise occurring in electronic circuitry. More particularly, the present invention relates to an electromagnetic interference (EMI) filter, which may be embedded in a printed circuit board (PCB) of any electronic circuitry, or used as a stand-alone filter component.

Operation of computers and other electronic devices is usually accompanied by unwanted noise generated in the same device or transmitted from another apparatus. As processing speeds increase, radiated emission and crosstalk phenomena are becoming more and more pronounced, that cause undesirable EMI. EMI manifests itself in equipment malfunction and/or failure. Above factors result in dramatic increase in electro-magnetic interference suppression requirements on equipment in major electronics markets.

Wires, harnesses and interconnection cables are one of major sources of radiated emission and susceptibility in modern electronic equipment. Conductors comprising harnesses and cables are efficient radiating elements and frequently are a significant source of electro-magnetic interference between co-located electronic equipment.

One of the techniques used for reduction of EMI is cable shielding. U.S. Pat. No. 4,514,029 to Lax, et al. describes a shielded connector for a shielded electrical cable that reduces radio frequency and EMI which comprises a pair of opposed interconnected shield members enclosing the insulated conductors of the cable.

Unfortunately, in some cases the cable shielding cannot be applied due to cost, weight or other practical considerations. The alternative to shielding, as a measure for EMI suppression, is EMI filtering of in/out interconnection cables and wires.

Prior art in regard to EMI filtering of cables and conductors includes the following:

U.S. Pat. No. 6,142,829 to O'Groske, et al. describes a ferrite electromagnetic interference suppressor element surrounding the conductors of the cable and all of which are enclosed and incorporated within an connector assembly.

U.S. Pat. No. 5,635,775 to Colburn, et al. describes a PCB mount EMI suppressor in a form of a ceramic capacitors array which is attached to a ground of the PCB and which can be adapted to a number of different types of connector design and configuration.

U.S. Pat. No. 4,383,225 to Mayer describes cables with high immunity to high amplitude electro magnetic pulses and U.S. Pat. No. 4,383.225 to Mayer describes a RF interference suppressing cable which include a magnetic material.

International Application PCT/IL9900567 to Axelrod, et al. incorporated here by reference as if fully set forth herein, discloses the application of glass-coated microwires with amorphous metal core as the basic element for EMI-protection of in/out conductors. In International Application PCT/IL9900567, the filter construction is in the form of bandages, tapes, or sleeve tubes to be added on existing or newly assembled conductors.

Such filters, although effective in significant suppression of EMI in in/out conductors and cables, cannot be used as EMI filters for installation on customer PCBs or within electrical connectors.

The present invention fulfills this gap and provides other related advantages.

### SUMMARY OF THE INVENTION

According to the present invention, EMI filtering is done by embedded amorphous metal in a form of ribbons and/or microwires as a part of a PCB construction, rather than by tubular shielding envelopes around individual conductors.

The present invention, discloses an EMI filters having a planar structure, particularly useful in single and multilayer PCBs, hybrids or any other structures used for manufacturing of electronic circuits and components.

Amorphous metals in a form of microwires an/or ribbons, are located in these planar structures in one or more stacked PCB layers, and are used as EMI suppression elements due to their significant absorption properties at radio frequency (RF) and microwave frequencies.

Planar structures for EMI filter based on PCB-embedded amorphous metals, stated below as objects of the invention, have several significant advantages in comparison with tubular EMI suppressing bandages.

In accordance with the present invention, there is provided an electromagnetic interference filter assembly comprising: (a) at least one electrical signal or power conductor located in the first PCB layer; (b) at least one other layer (the second PCB layer) comprising amorphous metals in a form of microwires, powder and/or ribbons, having opposed first and second surfaces, the at least one signal or power electrical conductor in close proximity to the first surface of the at least one ribbon and/or microwire-filled layer.

For even better filtering performance, two conductive layers may be used above and below the above two PCB layers, thus comprising electromagnetic shield of the above two layers. These two conductive layers may be interconnected by means of numerous plated-through holes.

In accordance with the present invention, there is provided an EMI filter comprising a plurality of stacked filter layers, each filter layer of the plurality of stacked filter layers comprises: (a) a first and a second layers filled with amorphous metals microwires and/or ribbons; (b) at least one signal or power conductor sandwiched between respective inner surfaces of the first and the second layers filled with amorphous metals in a form of microwires and/or ribbons.

For even better filtering performance, a first and a second conductive layer in intimate contact with the respective outer surfaces of the first and the second layer filled with amorphous metals in a form of microwires and/or ribbons.

In accordance with the present invention there is provided an EMI filtered transmission line(s) comprising of: (a) at least one pair of conductors carrying a functional signal or power current in a differential mode and, (b) an array of PCB layers, filled with amorphous metals in a form of microwires, powder and/or ribbons, surrounding the at least one pair of conductors wherein a region in close proximity to the at least one pair of electrical conductors is substantially free of said magnetic material-filled layers.

In accordance with the present invention there is provided a method for suppressing electromagnetic interference in functional currents comprising the steps of: (a) providing a functional current carried in at least one conductor or in at least one conductor pair and, (b) placing said at least one conductor or pair in close proximity to a PCB layer filled with amorphous metals in a form of microwires and/or ribbons.

It is therefore an object of the invention to use well-established and low-cost PCB production technology.

Another object of the invention is to achieve miniaturization of EMI filter structure due to high conductors density typical for modern PCBs.

Still another object of the invention is a significant cost reduction due to the fact that similar or better RF attenuation is achieved by means of much smaller amount of amorphous metals in a form of microwires or ribbons.

Yet another object of the invention is a ability to manufacture custom PCB-embedded EMI filters saving place on the PCB traditionally occupied by EMI filter components.

It is one more object of the invention to achieve much better common-mode attenuation at frequencies above 300 MHz and up to 40 GHz including microwave frequencies as compared with most of other available EMI filter components.

It is further an object of the invention to easily achieve electromagnetic shielding of lossy microwire and/or ribbons and current-carrying structures, which prevents undesirable parasitic coupling of RF noise radiation to the current-carrying structures and better filter common-mode attenuation performance.

It is an additional object of the invention to achieve much better control of conductors geometry and layout due to the use of photolithography or any other technology, which makes possible to achieve better symmetry of the signal-carrying conductors and as a result lower “leakage inductance” of the common-mode EMI filter, that leads to lower losses and lower waveform distortion to high-speed functional differential signals.

Other objects and goals of the present invention will become apparent upon reading the following description in conjunction with the following figures.

### BRIEF DESCRIPTION OF THE FIGURES

FIGS. 1A and 1B show respectively a longitudinal and a traverse cross section of a glass-coated microwire;

FIG. 2 shows a magnetic hysteresis of a glass-coated microwire;

FIGS. 3A and 3B show respectively the relative real part of permeability and the relative imaginary part of permeability of a glass-coated microwire versus frequency;

FIGS. 4A and 4B show lines of magnetic field around balanced signal pair due to differential mode currents;

FIG. 5 shows basic configurations of the electromagnetic filter assembly;

FIG. 6 shows a cross section of the microwire-filled layer;

FIG. 7 shows a cross section of a multilayer EMI filter;

FIGS. 8A and 8B show an exploded view of EMI filters,

FIG. 9 shows a multiple pass of a conductor in the same PCB filter layer;

FIG. 10 shows an hybrid EMI filter comprising PCB EMI filter section with embedded amorphous metals connected in series with a conventional common-mode choke;

FIG. 11 shows the important structural parameters of a EMI PCB filter;

FIG. 12 shows a cross section of an EMI filtered transmission line;

FIG. 13 shows an EMI PCB filter packaged in standard SMT or in a through-hole package;

FIG. 14 Shows an EMI PCB filter connected to a customer PCB by a connector or a harness;

FIG. 15 shows a custom EMI PCB filter being a part of a customer PCB;

FIG. 16 Shows a custom EMI PCB filter being a part of a customer motherboard; and

FIG. 17A and 17B show a top view and an exploded view respectively of the construction of an EMI filtered connector incorporating amorphous metals in a form of microwires or ribbons.

### DETAILED DESCRIPTION OF THE EMBODIMENTS

The present embodiments herein are not intended to be exhaustive and to limit in any way the scope of the invention, rather they are used as examples for the clarification of the invention and for enabling of other skilled in the art to utilize its teaching.

1. Principle of Operation of RF Filter Incorporating Amorphous Metals in a Form of Microwires and/or Ribbons.

In the EMI filters disclosed in the present invention, absorption of radio frequency (RF) energy is preferably done by means of a amorphous metals in a form of glass-coated microwires wherein the microwire is made of a soft ferromagnetic metallic alloy, although uncoated ferromagnetic metallic ribbons or powders can be used as well.

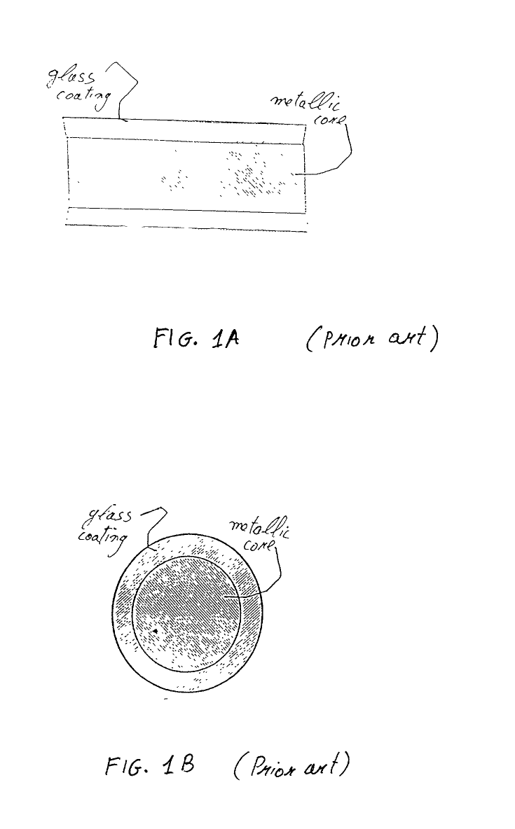

A longitudinal sectional view of a glass coated microwire, is shown in FIG. 1A, while FIG. 1B illustrates a traverse sectional view of the glass coated microwire.

The glass-coated microwire has a metallic core and a glass coating. Microwires as illustrated in FIG. 1A and FIG. 1B are known in the art. e.g. U.S. Pat. No. 5,240,066 to Gorynin, et al. describes a method for manufacturing glass-coated microwires. The typical diameter of the microwire core is in the range of about 6-10 microns, with the thickness of the glass coating about 1-3 microns. However a variety of glass-coated microwires having a diameter in range of about of 0.5 μm to about 100 μm can be used as well.

The glass-coated microwires, with filtering properties according to the present disclosure have a ferromagnetic core made either of an amorphous alloy, a nano-crystalline alloy, a microcrystalline alloy or a combination thereof.

The ferromagnetic ribbons are made of thin strips of amorphous metallic material having a typical thickness of about 2 to 50 micrometers and width in the range of about 2-300 millimeters.

The ferromagnetic powder is made of amorphous metal particles having dimension in the range of several nanometers to several micrometers.

In a preferred embodiment, the ferromagnetic substance (the core of the microwire or the material of the ribbon and the material of the powder particles) includes a (CoMe)BSi alloy, where Me is a metal from a set of Fe, Mn, Ni and Cr, or any alloy of a combination thereof.

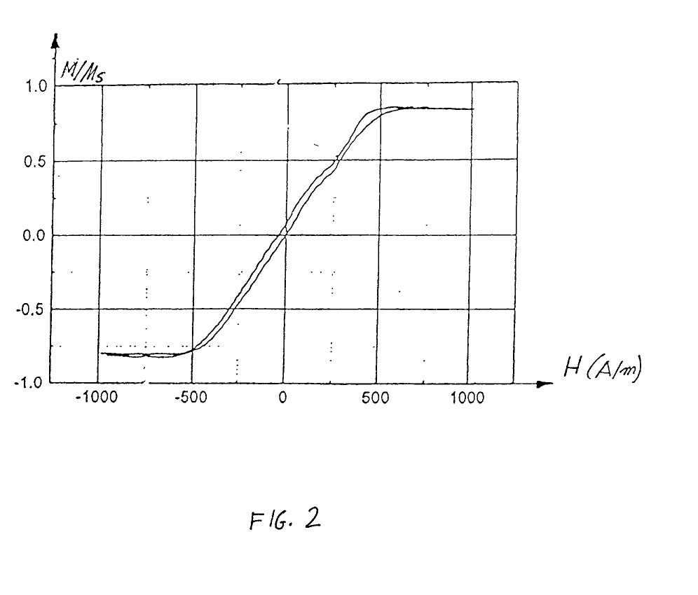

FIG. 2 illustrates the magnetic hysteresis characteristic of a sample consisting of ferromagnetic substance (e.g. a glass-coated microwire, an uncoated amorphous metallic strip or a powder), which has a “flat” shape.

Thus, when the relative magnetic flux is illustrated as a function of the magnetic field intensity (A/m), the relative magnetic flux exhibits first a linear region and then a saturation region for higher values of the magnetic intensity.

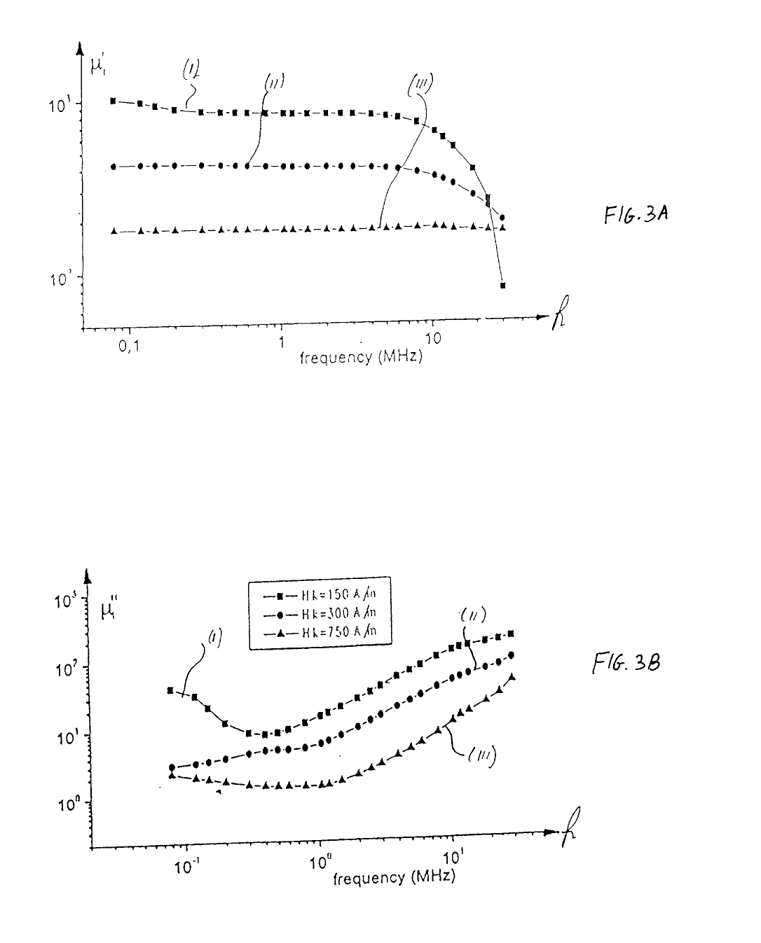

FIGS. 3A and 3B illustrate the relative real (μ′) and imaginary (μ″) permeability of a microwire as a function of frequency. Both FIGS. 3A and 3B show the relative permeability of microwires based on metallic materials with different coercive force (He). In these figures different curves correspond to different values of He. Graphs-I indicate permeability for He of 150 A/m, graphs-II indicate permeability for He of 300 A/m and graphs-III indicate permeability for He equal to 750 A/m.

The high value of the relative permeability over a wide range of frequencies enables the useful application of the magnetic material for EMI suppression as explained below:

The total complex impedance Z_{Tot} presented by the filter to the common mode interference current (noise) has a real and an imaginary component:

Z_{Tot}=Re[Z_{Tot}]+jIm[Z_{Tot}]

Where the greater Z_{Tot} is, the greater is the EMI suppression.

The relative real part of the permeability (μ′) contributes to Im[Z_{Tot}] (the inductive or reactive part of the impedance), while the relative imaginary part of the permeability (μ″) is responsible for the real (or dissipative)] part Re[Z_{Tot}] of the total impedance Z_{Tot}

The dissipative part Re[Z_{Tot}] of the total impedance is the dominant part in the upper frequency range, usually above 100 MHz.

We will hereafter assign the term “magnetic material” to a tangible entity including a glass-coated microwire, a ferromagnetic amorphous metallic ribbon (strip), a ferromagnetic powder or a combination thereof which has substantially typical magnetic properties as are shown in FIGS. 2, 3A and 3B.

The interaction between a magnetic material and the RF noise current in a co-located conductor(s) will now be explained:

Metallic wire(s) carrying RF (noise and signal) currents are sources of RF electromagnetic fields. It has been shown that microwire fiber interacts primarily with external RF electromagnetic field having a magnetic field component parallel to the microwire axis.

At high frequencies this interaction results in significant energy dissipation, so that dissipated electromagnetic energy is transformed into heating of the microwire metallic core.

Thus, for effective interaction with the electromagnetic field of the current connector and greater RF losses, the microwire fibers must be oriented perpendicular to the flow of the RF current.

It should be realized that at frequencies above 30 MHz, the purpose of most signal and power EMI filters is to attenuate exclusively the common-mode current (noise) components, causing minimum attenuation to the functional differential-mode currents (functional currents).

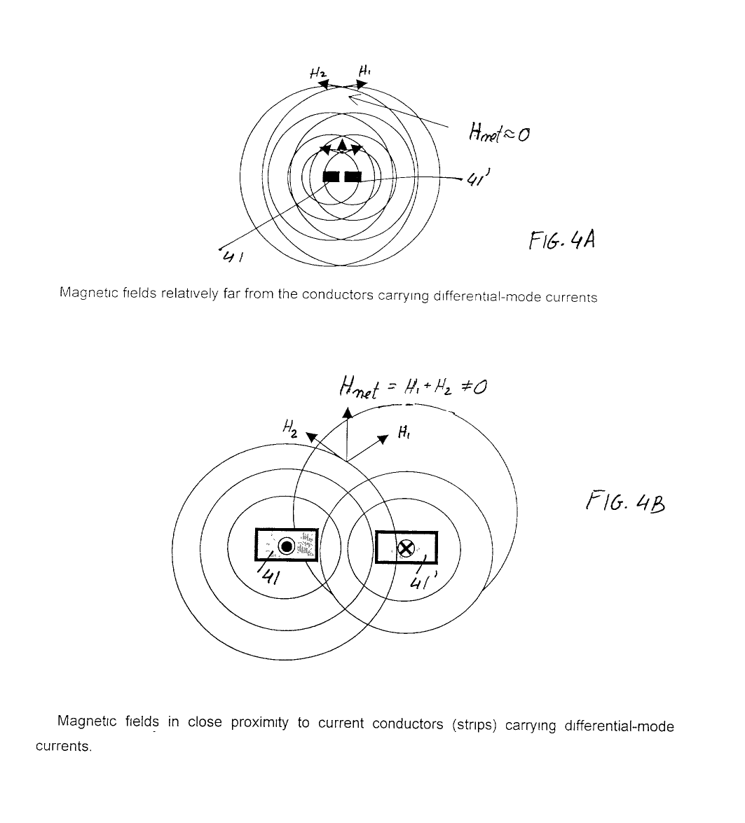

Filtering of common-mode noise current from high-speed functional current (up to 40 GHz) is effectively done using basic balanced structures (differential mode), as explained with the aid of FIGS. 4A and 4B to which reference is now being made.

As shown in FIGS. 4A and 4B, functional currents are transferred using a balanced structure composed of two parallel strip conductors 41 and 41′, wherein the functional current in conductor 41 equals strictly in amplitude and is opposite in phase to the functional current in conductor 41′.

As a result, in most of the space surrounding strips 41, 41′, magnetic field of the first (forward-directed) current H₁ is effectively compensated by magnetic field H₂ due to oppositely directed returned current, and hence hardly any magnetic field due to the functional current exists to affect a microwire (not shown) and to become dissipated by its core.

In such a case, which is the case of popular high-speed digital communication lines, only a residual small amount of the signal energy Hₙₑₜ as shown in FIG. 4B, comes into interaction with the microwire fibers, this is primarily in areas located very close to strips 41, 41′, where magnetic field due to current in conductor 41 is not totally compensated by magnetic field due to current in conductor 41′, e.g. Hₙₑₜ=H₁+H₂≠0.

This makes possible to achieve low losses for functional current consisting of high-speed balanced signals, as required for reliable long-range communication.

Thus, closely spaced strips with balanced currents (the differential mode) provide three advantages: lower losses for functional differential-mode currents, more compact EMI filter structure, and lower costs due to smaller amount of microwire material and smaller PCB area.

In case of single-ended signal lines, attenuation is caused both to functional current and noise current. For this reason single-ended structures are suitable for EMI filtering of power leads and relatively low-speed signals.

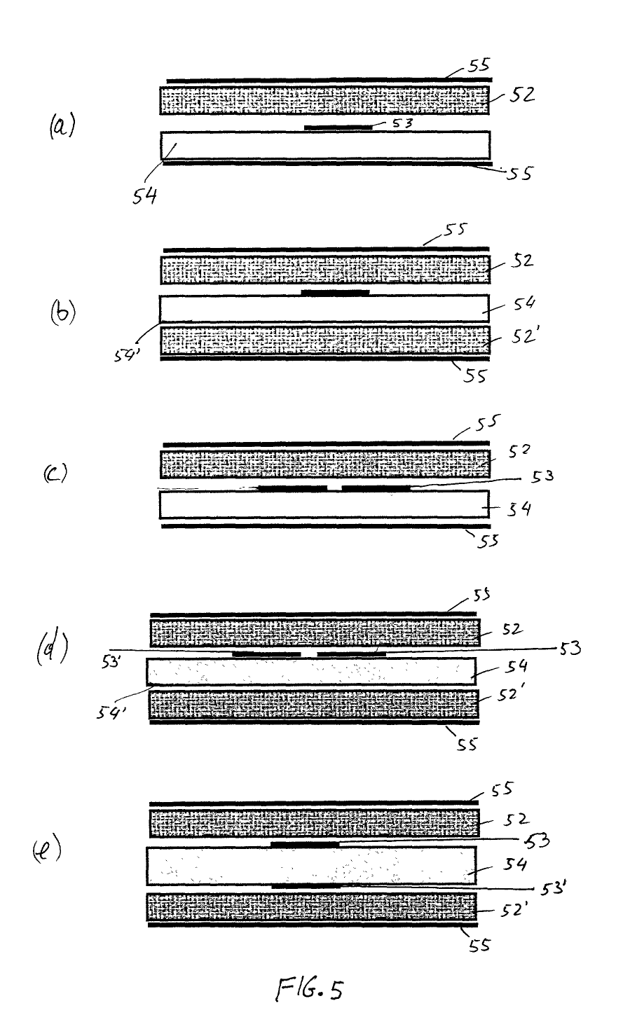

The basic planar structures incorporating magnetic material lossy layers (layers which cause energy losses) are shown in parts (a) to (e) of FIG. 5. These structures are building blocks for more complicated filter structures as described below.

FIG. 5(a) shows a single ended conducting strip 53 sandwiched between a layer 52 filled with magnetic material and a layer of a circuit laminate 54 such as glass-epoxy layer. Both outer faces of the structure are plated with copper layers 55 which are electrically grounded. It should be noted that laminate 54 is not vital for the functionality of the magnetic material-filled layer

FIG. 5(b) shows a similar structure to that shown FIG. 5(a) having an additional layer 52′ filled with magnetic material. Layer 52′ is located on the outer surface 54′ of circuit laminate 54.

FIG. 5(c) shows a similar construction to that shown in FIG. 5(a), having an additional conducting strip 53′ to form with conductive strip 53 a balanced current-carrying structure.

FIG. 5(d) shows a similar structure to that shown FIG. 5(c), having an additional layer 52′ filled with magnetic material. Layer 52′ is located on the outer surface 54′ of circuit laminate 54.

FIG. 5(e) shows a similar structure to that shown FIG. 5(d) having current-carrying onducting strips 53 and 53′ on the opposite sides of circuit laminate 54.

Each layer 52, 52′ filled with magnetic material is composed of a great number of bodies or particles made of magnetic material which are the EMI energy absorbing substance of the layer.

For handling of magnetic material-filled layers during manufacturing of EMI filters, mechanical stability of these layers must be achieved. For this, several alternative are used: E.g. the use of woven and non-woven fabrics of microwire fibers or the use of a laminate in which microwire fibers, amorphous metallic ribbons or powder particles which are randomly distributed in the magnetic material-filled layer are mechanically stabilized by some reinforcing material, like epoxy, other polymeric material or in-organic filler.

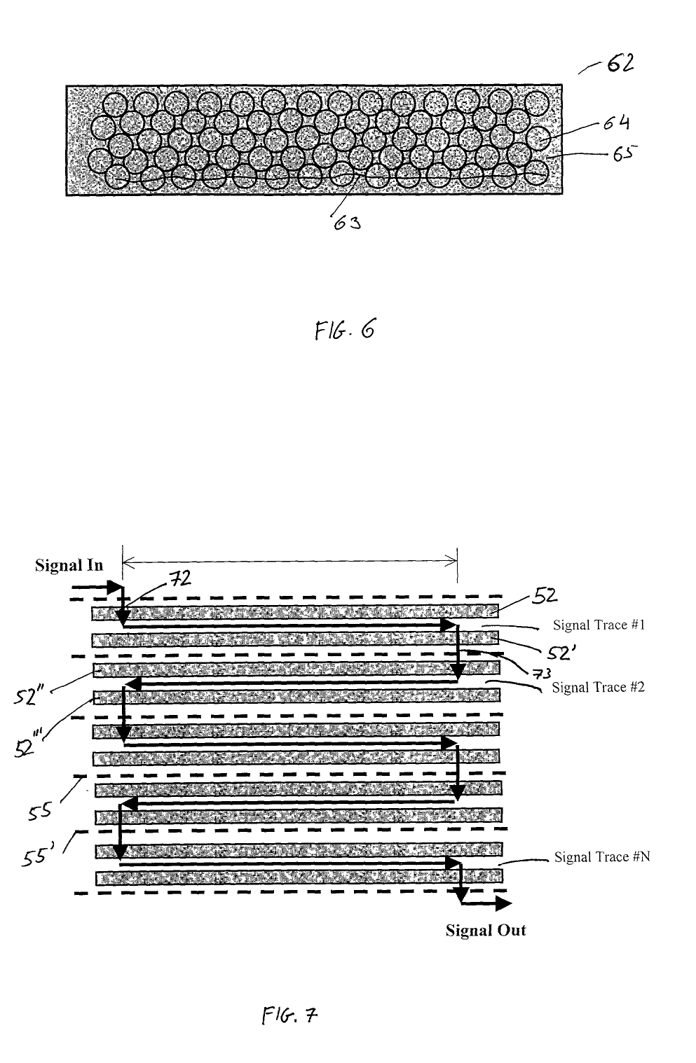

A cross-section of a filled-microwire layer is shown in FIG. 6.

In FIG. 6 each microwire-filled layer 62 contains one or more (typically about ten or more) layers 63 of magnetic material 64 embedded in a filling material 65.

For application as magnetic material embedded PCB EMI filter, magnetic material-filled layers 52 must have thickness ranging from several microns to several hundreds of microns. Magnetic material-filled layer 52 are then pre-shaped, and molded or glued into the surface of a glass-epoxy or other plastic material of the laminate 54 which supports conductor 53, and the whole filter assembly is attached to a customer PCB.

As is shown below, this assembly may occupy a whole area of the customer PCB or only some part of it.

Structures as shown in FIG. 5 are used for EMI filtering without any further modification. Naturally, greater suppression of common-mode noise component is achieved in cases when metallic strips carrying functional currents are surrounded by two layers of magnetic material-filled layers as is shown in parts (b), (d) and (e) of FIG. 5. It is obvious that for most commercial applications, more compact EMI filters using PCB multilayer structures are needed.

An example of a multiplayer filter structure employing basic filter structures given in FIG. 5 is shown in FIG. 7.

In FIG. 7, the signal arriving in “Signal in” terminal penetrates into the filter structure via a through-hole 72 (a vias). It passes then through a conductor segment called Signal Trace #1, which is located between two magnetic material-filled layers 52, 52′.

Construction of each such magnetic material-filled layer was discussed earlier. The signal traces then pass to the current conductor in Signal Trace #2 via metal plated through-holes 73.

For compact filter structures the direction of the current in Signal Trace #2 is in the reverse direction to the current in Signal Trace #1. Like Signal Trace #1, Signal Trace #2 runs between two magnetic material-filled layers 52″ and 52″′. Similarly, the signal then passes though the rest of all (N) Signal Traces until they reach the “Signal out” port.

While propagating between lossy magnetic material-filled layers, energy of common-mode current is steadily dissipated to the required level. The greater the required filter attenuation is, the greater must be the length of the conductor in each signal trace and the number N of the Signal Traces.

Parasitic capacitance between input and output ports of the filter or between different signal traces comprising the filter structure, may cause degradation in the filter attenuation at higher (typically at several hundreds of MHz) frequencies.

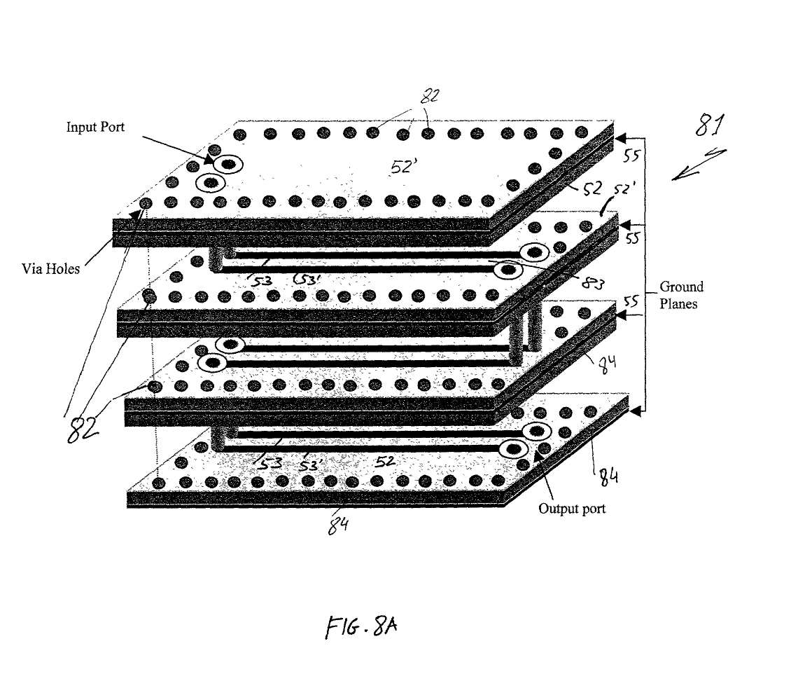

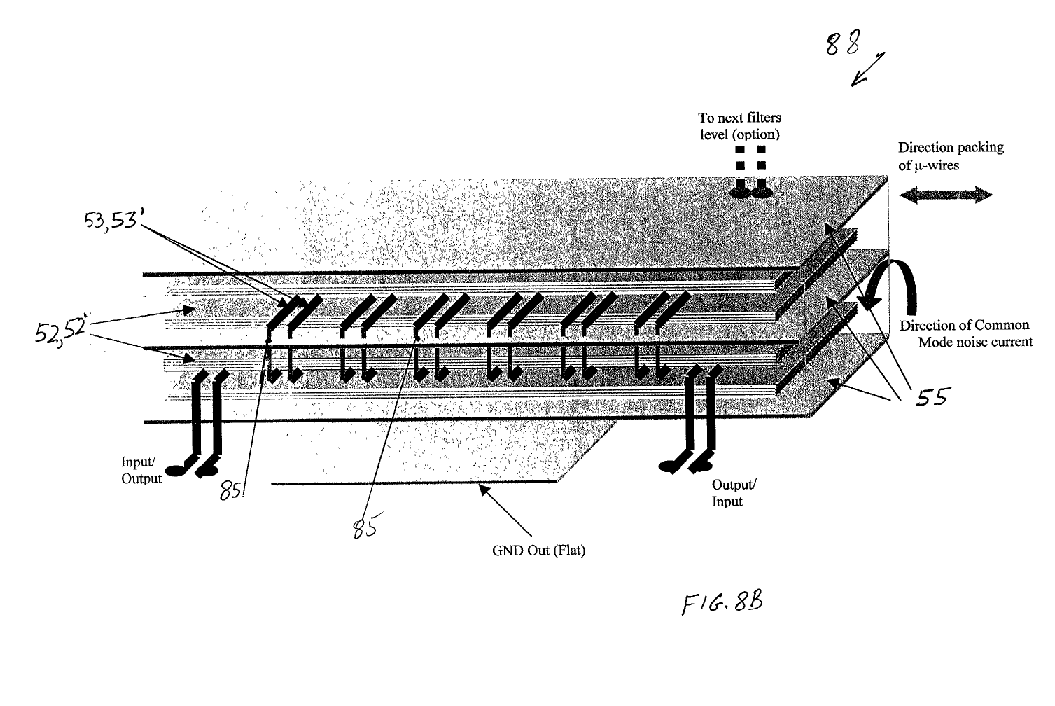

In order to prevent undesirable electromagnetic coupling between the signal traces, grounded conducting planes 55, 55′ shield each signal trace from both sides. Further shield improvement is achieved by shorting electrically all ground layers 55 via through-holes. The shortened through-holes 82 which are shown in FIG. 8 to which reference is now made are drilled along both sides of conductors 53, 53′ in signal traces 83. This shall reduce the leakage of electromagnetic energy from laminate edges 84. Even better shielding is achieved by plating of all edges 84 of assembly 81, so that all the ground layers 55 are shorted continuously to each other by this edge plating.

In above example signal leads are traced between two layers filled with magnetic material 52,52′. In some other designs there is only a single layer of absorbing material in a form of microwires or amorphous metal ribbon adjacent to the signal-carrying traces.

Another configuration which utilizes the construction shown in FIG. 7 and which extends the path of filtered conductors inside the filter without the need for a large numbers of filtering layers is shown in FIG. 8B to which reference is now made.

FIG. 8B shows a filter 88 in which signal carrying electrical conductors 53,53′ are coiled around two layers of magnetic material 52, 52′ having between them a layer 55 of conductive material. Each helical turn, conductors 53,53′ traverse twice conductive layer 55, via insulating through-holes 85.

2. Important Performance Parameters.

2.1 Common-Mode Rejection.

Attenuation of PCB magnetic material embedded EMI filters is mainly a function of the following parameters:

a) the total length of interaction between signal strips and magnetic material-filled layers;

b) the thickness of magnetic material-filled layers;

c) the proximity of magnetic material-filled layers and signal traces.

In order to achieve sufficient attenuation to common-mode currents, the total interaction length must be long enough. In cases of short signal traces when the filter must be of physically small area, the short signal trace must be compensated by a greater number of signal traces.

Greater attenuation is achieved by means of thicker magnetic material-filled layers. Thickness of magnetic material-filled layers is limited by the total allowable filter thickness.

Greater attenuation is also achieved by closer location of layers filled with microwires and/or amorphous metal ribbons 52,52′ relative to the filtered signal strips 53. While first RF absorbing layer 52 is laid directly on the signal-carrying, strips, the other absorbing layer 52′ is always separated from the strips by the thickness of circuit laminate 54 which supports the signal strips.

For greater common-mode rejection, thickness of circuit laminate must be as small as possible (typically 0.1 mm).

Greater attenuation at lower frequency band (30-100 MHz) may be also achieved by the use of more than one path of the signal conductor 53 in the same plane. This technique shall increase significantly the length of interaction between the signal traces and the absorbing amorphous metal material. Drawback of this technique is increased coupling between input and output of meander-like pattern 92, of filter 90 shown in FIG. 9 to which reference is now made.

Filter 90 results in degraded performance of filter section located in first signal layer 95 accommodating pattern 92 at frequencies above 200 MHz. In order to compensate for this drawback signal traces 53 located in other planes, must consist of a single trace.

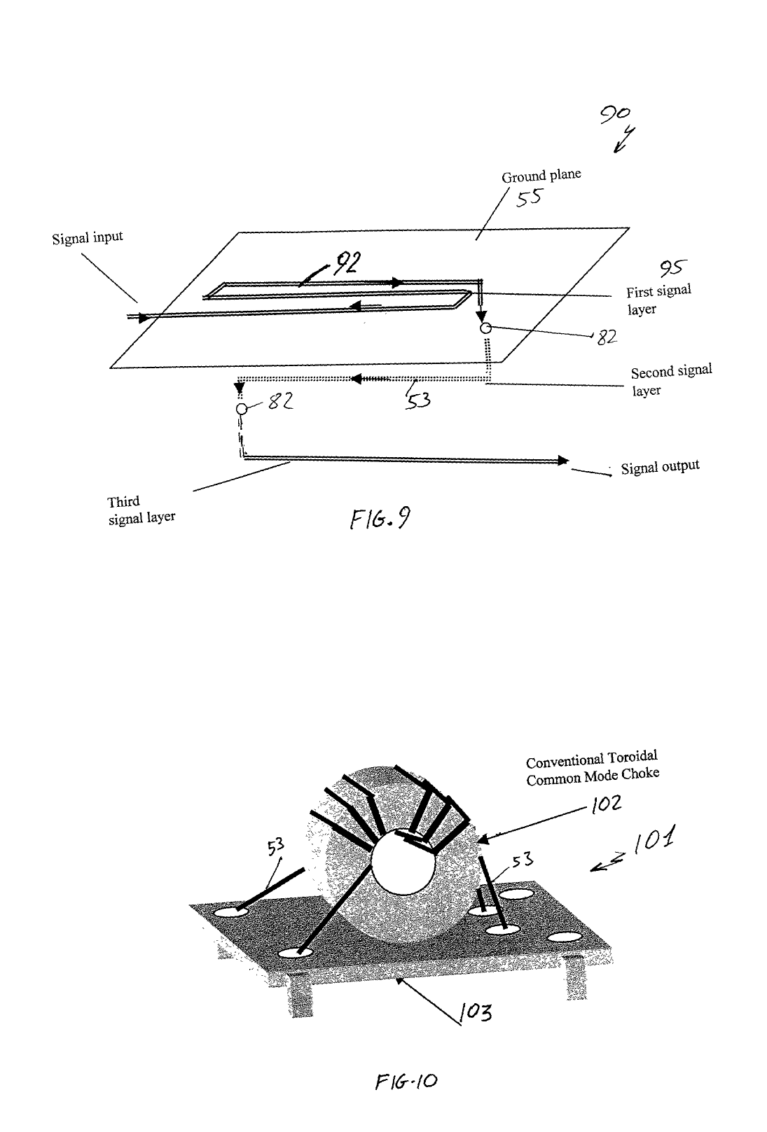

Further improvement of the filter attenuation properties below 100 MHz is achieved by a use of a hybrid design 101 shown in FIG. 10 to which reference is now made.

This design features a series connection of a common mode toroidal-choke (prior art) 102 and a PCB EMI filter 103 in which magnetic material is embedded.

In this combination, high values for common mode attenuation for frequencies below 100 MHZ is achieved by choke 102 which includes also different magnetic materials than that which were defined in the present invention, e.g. ferrite or other ferromagnetic amorphous metal on which signal carrying conductor 53 is turned around, while the attenuation of the common mode at higher frequencies is achieved by the PCB filter 103.

The overall attenuation of filter 101 of the common mode current is the sum of the attenuation provided by components 102 and 103.

For high-speed signal applications it is important that the filter structure provides proper value of the characteristic impedance for functional (differential-mode) currents. This is necessary in order to achieve low return loss in required frequency band. The low return loss and low dissipative loss requirements are applicable for the differential-mode signals, while high total attenuation (loss) requirement is applicable only to the common-mode currents.

The most promising cross-section of planar transmission line that can enable to satisfy all above conditions is shown in FIG. 11.

In this transmission line 111, energy of the differential-mode current is concentrated in the Area I (between two signal strips), while the energy of the common mode is primarily concentrated in regions II and III. Since region I and regions II+III do not overlap, it is possible to achieve low attenuation of the differential mode and significant attenuation of the common mode by location of the lossy materials in regions II and III only.

In order to achieve low return loss, it is required to design properly the dimensions of the transmission line cross-section, so that the characteristic impedance of the differential mode signal is as close as possible to the nominal value (typically 100 Ohms).

In transmission line 111, two balanced conductors 53,53′ are carrying the differential-mode signal currents. The electromagnetic field due to these functional currents is concentrated primarily in the region I, which is free of lossy materials (microwires or ribbons made of amorphous metal materials). This results in a relatively low attenuation of the functional signal.

By looking back into FIG. 4 and its accompanying explanation, it can be seen that the resultant magnetic field Hₙₑₜ due to the functional currents is confined to the space near the conductors (region I) and hence will not be attenuated by the RF absorbing layers 52,52′ which are located in region II and region III which are remote enough from conductors 53, 53′. However, the common-mode current whose magnetic field extends further then Hₙₑₜ is heavily absorbed by magnetic material-filled layer 52,52′ at region II and region III.

As discussed earlier, EMI filter must provide minimal attenuation to all functional currents. In the case of balance communication lines, low attenuation must be provided to differential-mode currents propagating on two-strips. In accordance with considerations brought before, it is desirable to reduce spacing between the balanced strips 53,53′ (4-6 mil for current PCB technology).

Characteristic impedance of balanced communication lines must be controlled in order to avoid undesirable increase in return loss, accompanied by ringing and subsequent waveform distortions. FIG. 12 demonstrates typical cross-section of a balanced signal-carrying structure 122. This figure includes definition of physical parameters to be controlled in order to achieve the required value of the characteristic impedance of the EMI filters based on the PCB-embedded magnetic material.

The width of signal strips 53,53′(W), their separation (S) and thickness of all dielectric layers (H1, H2 and H3), including that of magnetic material-filled layer, must be carefully designed.

Characteristic impedance depends also on dielectric constants of circuit laminate material (ξ_{g}) and that of magnetic material-filled layer (ξₘ).

Typical values for the parameters shown in FIG. 12 are: W is about 5 mil., S is about 5 mil., H1 and H3 about 15 mil., and H2 is about 4 mil. ξ_{g} and ξₘ are both between about 2 and about 3.

However, other values for the parameters shown in FIG. 12 can be used too such as: W is in the range of between about 0.2 mil. and about 150 mil., S is in the range of between about 2 mil. and about 100 mil., H1 and H3 are in the range of between about 1 mil. and about 50 mil. and H2 is in the range of between about 1 mil. and about 50 mil.

Illustrative properties of tested EMI filters based on the novel PCB-embedded magnetic material technology are shown in Table 1.

TABLE 1

| No. | Parameter | Measured values |
|---|---|---|
| 1 | Attenuation of Common-Mode | 10 dB and more @ 100 MHz |
| | Noise | 20 dB @ 200 MHz |
| | | 30 dB @ 300 MHz |
| | | above 40 dB at frequencies |
| | | greater than 400 MHz |
| 2 | Attenuation of Differential- | 0.5 dB @ 100 MBPS |
| | Mode current | 1.0 dB @ 300 MBPS |
| 3 | Crosstalk between adjacent | −40 dB and more @ 100 MBPS |
| | balanced signals | |
| 4 | PCB Physical dimensions | Length = 15-20 mm; |
| | | Width = 5-10 mm; |
| | | Thickness = 2.4 mm. |

4. Examples

EMI filters based on PCB-embedded microwire technology are realized in several forms all based on PCB-embedded with magnetic material, which are shown in FIGS. 13 to 17:

4.1 EMI filters packaged in standard surface mounted technology (SMT) or in standard through-hole packages;

PCB EMI filters are designed and manufactured for SMT in through-hole PCB designs. FIG. 13 demonstrates an EMI filter for 8 communication lines packaged in standard SMT in a through-hole package.

Lower-filtering costs per each filtered line is achieved when the component filters greater number of leads. These components incorporate small PCB with embedded magnetic material lossy layer(s). As shown in FIG. 13, typically input terminals are located on one side 131 of EMI filter 130, while output terminals are on the other side 132 of filter 130.

These components are manufactured as pin-to-pin compatibles for currently available electromagnetic compatible (EMC) filters manufactured by other vendors. Components with various attenuation characteristics are designed using various numbers of PCB-embedded layers of magnetic material.

4.2 Special filter PCBs connected to the customer PCB by a connector or a harness.

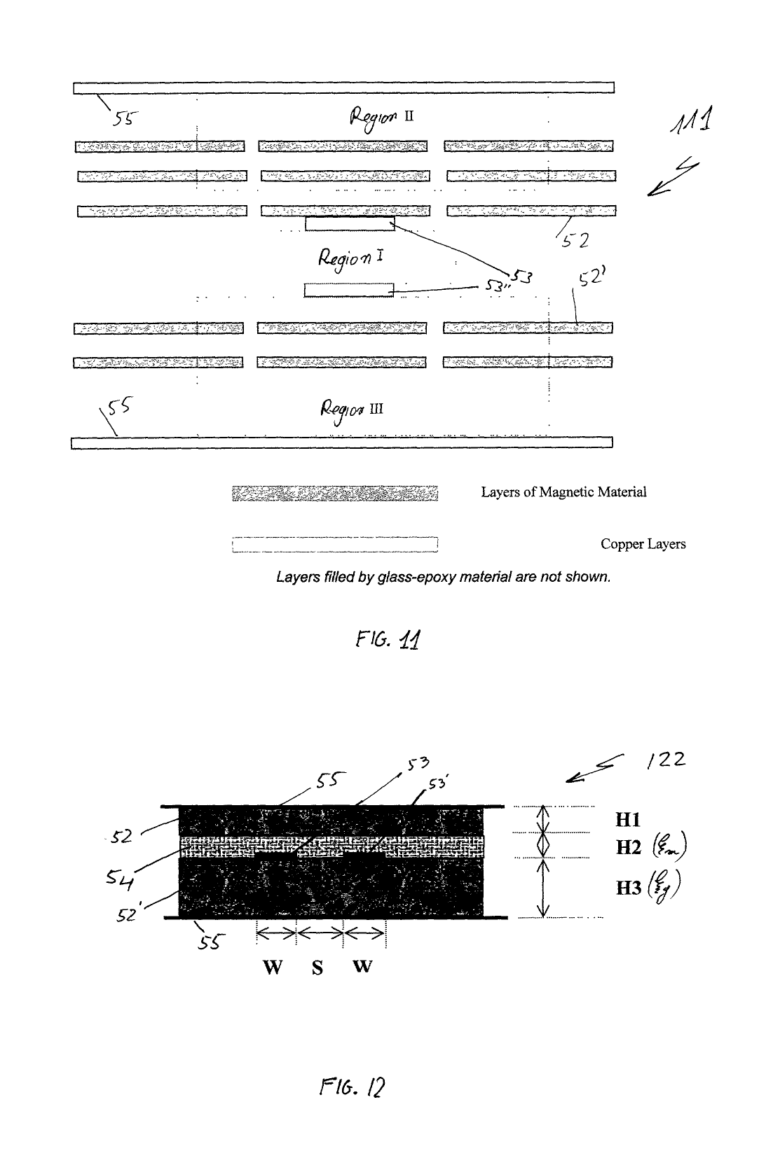

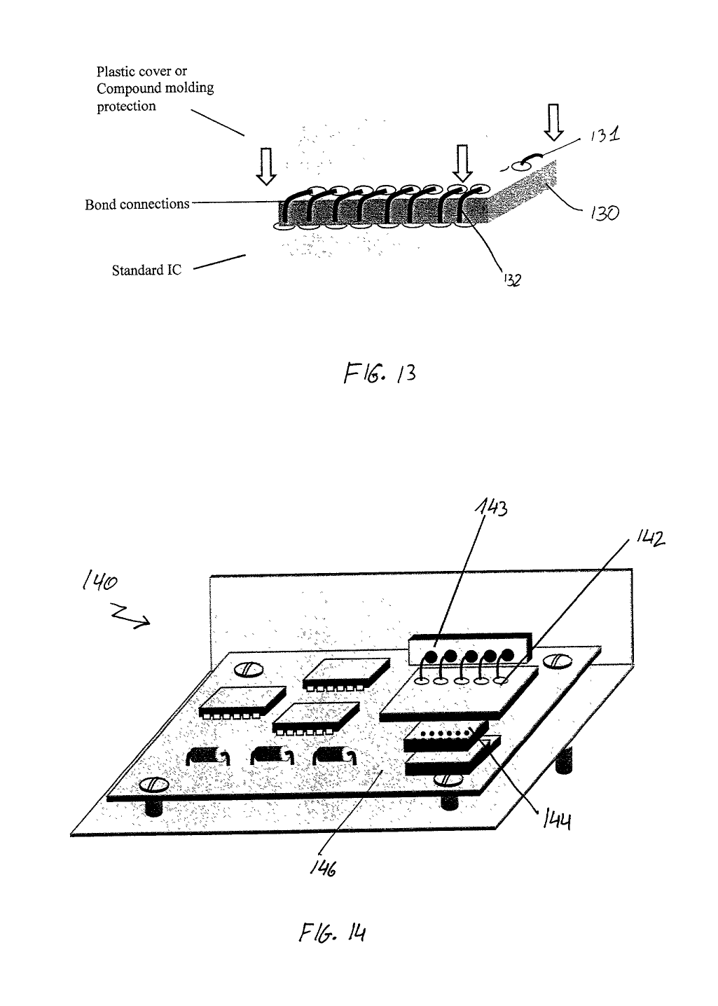

FIG. 14 demonstrates an embodiment 140 when filtering of In/Out signal and power leads are done using special “filter PCB” 142. This PCB is designed as custom or off-the shelf component.

Filter PCB 142 has two connectors: one being, typically, a system connector 143 used for connection of the filtered electronic equipment with external devices, and a second connector 144 is used for connection with the electronics of the filtered equipment.

In this way “filter PCB” 142 is a buffer device, and is installed in parallel to the host PCB 146 of the filtered equipment (piggy-back PCB design), or in parallel to the front panel (not shown). In both cases the filter PCB may filter signal and/or power leads of more than one in/out connectors. The approach demonstrated in FIG. 14 may save place on the host PCB, and is added to already existing electronic devices for solving EMI problems or for compliance with EMC standards needs.

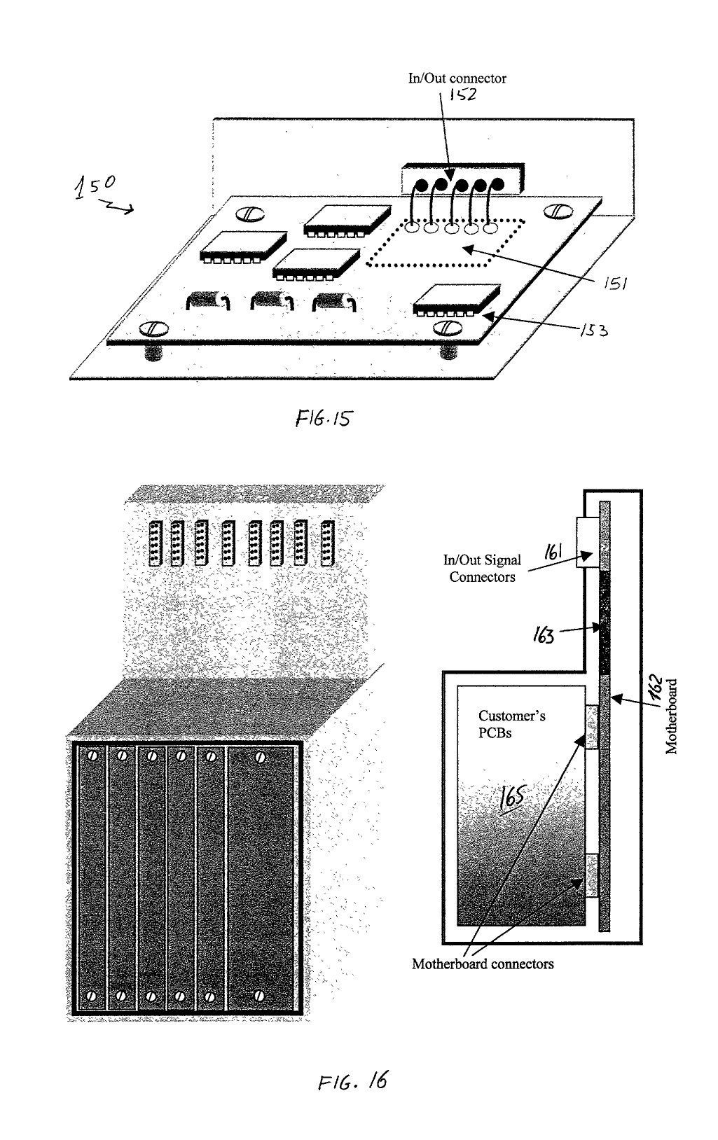

FIG. 15 demonstrates an embodiment 150 where a magnetic material lossy layer 151 is embedded into PCB layers of an host customer PCB 153. Microwire material occupies, typically, areas close to In/Out sockets 152.

4.3 Custom EMI filters being a part of the customer PCB or Motherboard;

FIG. 16 shows magnetic material layers embedded into internal layers of the back plane motherboard 162 e.g. of a large electronic equipment. In some back plane designs In/out connectors are located in a special area located relatively far from the area occupied by the customer PCBs 165.

Magnetic material 163 is embedded in the area between the In/Out signal connectors 161 and the area of customer PCBs 165. This design may make unnecessary to apply other filter components in area close to in/out connectors.

4.4 Filter-pin connectors employing PCB with absorbing layers.

Filtered connectors are used in electronic designs when filtering may not be done on the PCB, or in cases when already existing equipment must be upgraded for better emission or immunity EMI characteristics. This approach is used widely in military, naval, airborne, space, medical and other applications when filtered connectors may provide better filtering performance at higher frequencies (several hundreds of MHz).

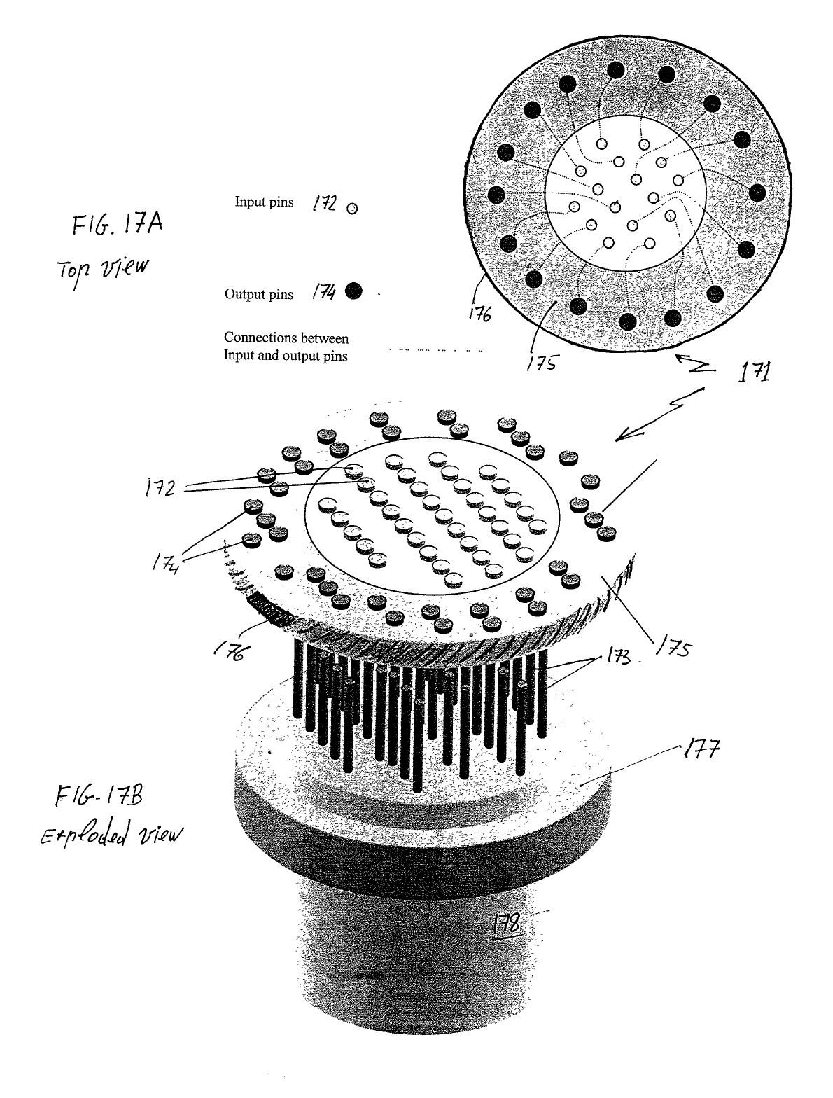

A special filter EMI suppressor for connectors is designed and manufactured as shown in FIGS. 17A and 17B which are respectively, a top and an exploded view of an EMI suppressor 171. EMI suppressor 171 incorporates at its center through-holes or SMT pads (input sockets) 172 for pins 173 of a filtered connector 178, and on its periphery; EMI suppressor 171 has through-holes or SMT pads (output pins) 174 for establishment of electrical contact with filtered electronic device (not shown).

Input pins 172 and output pins 174 should be one-to-one interconnected, as shown in FIG. 17A. These interconnects shall be traced in inner layers 175 filled with absorbing magnetic material of filter PCB.

Design of filter PCB 175 is similar to that shown in previous sections describing this invention. External layer 176 of filter PCB has to be a conductive ground layer, which must be in continuous contact with a metallic body 177 of connector 178. In some case this contact is established by means of metallic cylinder (not shown) serving as mechanical adapter located between body of connector 178 and EMI suppressor 171, thus also supporting suppressor 171.

While the invention has been described with respect to a limited number of embodiments, it will be appreciated that many variations, modifications and other applications of the invention may be made without departing from the spirit and scope of the invention.

What is claimed is:

1. An electromagnetic interference filter assembly comprising:
(a) at least one electrical conductor, and
(b) at least one magnetic material-filled layer having opposed first and second surfaces, said at least one electrical conductor in close proximity to said first surface of said at least one magnetic material-filled layer.

2. The electromagnetic interference filter assembly as in claim 1 wherein said at least one electrical conductor is supported by a first surface of a circuit substrate laminate.

3. The electromagnetic interference filter assembly as in claim 2 further comprising:
(c) a conductive layer in intimate contact with at least part of said second surface of said at least one magnetic material-filled layer.

4. The electromagnetic interference filter assembly as in claim 3 having a second conductive layer wherein the second conductive layer is in intimate contact with a portion of a second surface of said circuit laminate.

5. The electromagnetic interference filter assembly as in claim 2 wherein said circuit substrate laminate is a portion of a printed circuit board (PCB).

6. The electromagnetic interference filter assembly as in claim 1 wherein a range of said closed proximity is between about zero to about 2 milimeter.

7. The electromagnetic interference filter assembly as in claim 1 wherein said at least one electrical conductor carries a functional current.

8. The electromagnetic interference filter assembly as in claim 7 wherein said functional current having a frequency of between about 1 MHz and about 40 GHz.

9. The electromagnetic interference filter assembly as in claim 1 wherein said at least one magnetic material-filled layer includes a ferromagnetic substance in the form elected from the group consisting of glass-coated microwires, metal ribbons and powder particles.

10. The electromagnetic interference filter assembly as in claim 9 wherein said ferromagnetic substance is selected from the group consisting of an amorphous metallic alloy, a micro-crystalline alloy and a nano-crystalline alloy.

11. The electromagnetic interference filter assembly as in claim 9 wherein said ferromagnetic substance includes chemical elements selected from the group consisting of Co, Si, B, Fe, Ni, Cr, Mn and combinations thereof.

12. The electromagnetic interference filter assembly as in claim 9 wherein said glass-coated microwires having their longitudinal axis pointing toward the same direction.

13. The electromagnetic interference filter assembly as in claim 12 wherein said same direction has an inclination with respect to a segment of said at least one electrical conductor.

14. The electromagnetic interference filter assembly as in claim 9 wherein
(i) said glass-coated microwires have a diameter of between about 0.5 micrometers and about 100 micrometers;
(ii) said metallic ribbons have a thickness of between about 2 micrometers and about 50 micrometers, and
(iii) said powder particles have a diameter in the range of about several nanometers to about several micrometers.

15. The electromagnetic interference filter assembly as in claim 9 wherein said ferromagnetic substance has a relative real permeability of at least 10²

16. The electromagnetic interference filter assembly as in claim 9 wherein ferromagnetic substance has a relative imaginary permeability of at least 1.

17. The electromagnetic interference filter assembly as in claim 9 wherein a ferromagnetic substance is effected by a magnetic field intensity of at least about 0.02 Oe.

18. The electromagnetic interference filter assembly as in claim 1 wherein said at least one magnetic material-filled layer is selected from the group consisting of a fabric layer and a reinforced layer.

19. The electromagnetic interference filter assembly as in claim 18 wherein said fabric layer is selected from the group consisting of a woven fabric and a non-woven fabric.

20. The electromagnetic interference filter assembly as in claim 18 wherein said reinforced layer includes a reinforcing material selected from the group consisting of a glass fiber, an inorganic filler, a polymeric material and a combination thereof.

21. The electromagnetic interference filter assembly as in claim 3 wherein said conductive layer includes a material selected from the group consisting of copper, silver, aluminum and conductive polymer.

22. The electromagnetic interference filter assembly as in claim 3 wherein said conductive layer is electrically grounded.

23. The electromagnetic interference filter assembly as in claim 1 having two electrical conductors wherein a segment of the second electrical conductor and a segment of the first electrical conductor are in a plane parallel to said at least one magnetic material-filled layer.

24. The electromagnetic interference filter assembly as in claim 23 wherein a spacing between said two electrical conductors is between about 2 mil. and about 100 mil.

25. The electromagnetic interference filter assembly as in claim 2 having two electrical conductors wherein said two electrical conductors are supported by two opposite surfaces of said circuit substrate laminate.

26. The electromagnetic interference filter assembly as in claim 3 having a first and a second magnetic material-filled layer, said circuit substrate laminate is sandwiched between respective inner surfaces of said first and second magnetic material-filled layer.

27. The electromagnetic interference filter assembly as in claim 26 having a second conductive layer, said second conductive layers in intimate contact with an outer surface of said second magnetic material-filled layer.

28. The electromagnetic interference filter assembly as in claim 27 wherein said two conductive layers are electrically connected via through-holes in said circuit substrate laminate.

29. The electromagnetic interference filter assembly as in claim 28 wherein said two electrically connected conductive layers are grounded.

30. The electromagnetic interference filter assembly as in claim 1 wherein a thickness of said magnetic material-filled layer is between about 1 mil. and about 50 mil.

31. The electromagnetic interference filter assembly as in claim 2 wherein a thickness of said circuit laminate is between about 1 mil and about 50 mil.

32. The electromagnetic interference filter assembly as in claim 1 wherein a width of said at least one conductor is between about 0.2 mil and about 100 mil.

33. An electromagnetic interference filter comprising a plurality of stacked filter layers, each filter layer among said plurality of stacked filter layers comprises:
(a) a magnetic material-filled layer; said magnetic material-filled layer having an inner and an outer surface;
(b) at least one electrical conductor in closed proximity to said inner surface of said material-filled layer and,
(c) a conductive layer in intimate contact with said outer surface of said magnetic material-filled layer.

34. The electromagnetic interference filter as in claim 33 wherein said at least one electrical conductor in a first of said each filter layer is electrically connected to said at least one conductor in a second of said each filter layer.

35. The electromagnetic interference filter as in claim 33 wherein said conductive layers in intimate contact with said outer surface of said magnetic material-filled layer in each filter layer are electrically connected via through-holes in each said filter layer.

36. The electromagnetic interference filter as in claim 35 wherein said electrically connected conductive layers in each filter layer are grounded.

37. The electromagnetic interference filter as in claim 33 wherein said at least one electrical conductor in said each filter layer is supported by a circuit substrate laminate.

38. The electromagnetic interference filter as in claim 37 wherein said circuit substrate laminate is a portion of a printed circuit board (PCB).

39. The electromagnetic interference filter as in claim 32 wherein said at least one electrical conductor in said each filter layer is insulated.

40. The electromagnetic interference filter as in claim 32 wherein said at least one electrical conductor in said each filter layer carries a functional current.

41. The electromagnetic interference filter as in claim 40 wherein said functional current having a frequency of between about 1 MHz and about 40 GHz.

42. The electromagnetic interference filter as in claim 33 wherein said magnetic material-filled layer includes a ferromagnetic substance in the form selected from the group consisting of glass-coated microwires, metal ribbons and powder particles.

43. The electromagnetic interference filter as in claim 42 wherein said ferromagnetic substance is selected from the group consisting of an amorphous metallic alloy, a micro-crystalline alloy and a nano-crystalline alloy.

44. The electromagnetic interference filter as in claim 42 wherein said ferromagnetic substance includes chemical elements selected from the group consisting of Co, Si, B, Fe, Ni, Cr, Mn and combinations thereof.

45. The electromagnetic interference filter as in claim 42 wherein said glass-coated microwires having their longitudinal axis pointing toward the same direction.

46. The electromagnetic interference filter as ill claim 45 wherein said same direction has an inclination with respect to a segment of said at least one electrical conductor.

47. The electromagnetic interference filter as in claim 42 wherein
(i) said glass-coated microwires have a diameter of between about 0.5 micrometers and about 100 micrometers;
(ii) said metallic ribbons have a thickness of between about 2 micrometers and about 50 micrometers, and
(iii) said powder particles have a diameter in the range of about several nanometers to about several micrometers.

48. The electromagnetic interference filter as in claim 42 wherein said ferromagnetic substance has a relative real permeability of at least 10²

49. The electromagnetic interference filter as in claim 42 wherein said ferromagnetic substance has a relative imaginary permeability of at least 1.

50. The electromagnetic interference filter as in claim 42 wherein said ferromagnetic substance is effected by a magnetic field intensity of at least about 0.02 Oe.

51. The electromagnetic interference filter as in claim 33 wherein said magnetic material-filled layer is selected from the group consisting of a fabric layer and a reinforced layer.

52. The electromagnetic interference filter as in claim 51 wherein said fabric layer is selected from the group consisting of a woven fabric and a non-woven fabric.

53. The electromagnetic interference filter assembly as in claim 51 wherein said reinforced layer includes a reinforcing material selected from the group consisting of a glass fiber, inorganic filler, a polymeric material and a combination thereof.

54. The electromagnetic interference filter as in claim 33 wherein said conductive layers includes a material selected from the group consisting of copper, silver, aluminum and conductive polymer.

55. The electromagnetic interference filter as in claim 33 having two electrical conductors in said each filter layer, wherein a segment of the first electrical conductor and a segment of the second electrical conductor in said each filter layer are in a plane parallel to the stacked filter layers.

56. The electromagnetic interference filter as in claim 55 wherein a spacing between said two electrical conductors in said each filter layer is between about 2 mil and about 100 mil.

57. The electromagnetic interference filter as in claim 33 wherein a thickness of said magnetic material-filled layer is between about 1 mil. and about 50 mil.

58. The electromagnetic interference filter as in claim 37 wherein a thickness of said circuit laminate is between about 1 mil. and about 50 mil.

59. The electromagnetic interference filter as in claim 33 wherein a width of said at least one electrical conductor in said each filter layer is between about 0.2 mil. and about 100 mil.

60. The electromagnetic interference filter as in claim 33 wherein said at least one electrical conductor in at least one of said filter layer is winded in a meander-like pattern

61. The electromagnetic interference filter as in claim 34 wherein a continuous electrical conductor formed by said connection of at least one electrical conductor in a first of said each filter layer to said at least one electrical conductor in a second of said each filter layer, is helically coiled around two adjacent magnetic material-filled layer.

62. An electromagnetic interference filtered transmission line comprising of:
(a) at least two electrical conductors carrying a functional current in a differential mode;
(b) an array of magnetic material-filled layers surrounding said at least two electrical conductors;
wherein a region in close proximity to said at least two electrical conductors is substantially free of said magnetic material-filled layers.

63. The electromagnetic interference filtered transmission line as in claim 62 wherein a range of said close proximity is between about zero and about 50 mil.

64. The electromagnetic interference filter assembly as in claim 1 wherein said at least one electrical conductor of the filter assembly is connected to an electrical trace conductor of a customer PCB.

65. The electromagnetic interference filter assembly as in claim 64 wherein said connection is via a connector on said customer PCB.

66. The electromagnetic interference filter assembly as in claim 64 wherein said customer PCB is a part of a larger PCB.

67. The electromagnetic interference filter assembly as in claim 64 wherein said customer PCB is included in electronic equipment.

68. The electromagnetic interference filter assembly as in claim 64 wherein said electrical conductor is connected to a pin of an electrical connector.

69. The electromagnetic interference filter assembly as in claim 64 wherein said filter assembly is connected in series to a conductor of a common mode choke.

70. A method for suppressing electromagnetic interference in functional currents comprising the steps of:
(a) providing a functional current carried by at least one conductor and,
(b) locating said at least one electrical conductor in close proximity to a magnetic material-filled layer.

71. The method for suppressing electromagnetic interference in functional currents as in claim 70 wherein said at least one electrical conductor is supported by a circuit substrate laminate.

72. The method for suppressing electromagnetic interference in functional currents as in claim 70 wherein a range of said close proximity is between about zero and about 8 mil.

73. The method for suppressing electromagnetic interference in functional currents as in claim 70 wherein said at least one electrical conductor is insulated.

74. The method for suppressing electromagnetic interference in functional currents as in claim 70 wherein said functional currents having a frequency of between about 1 MHz and about 40 GHz.

75. The method for suppressing electromagnetic interference in functional currents as in claim 70 wherein said magnetic material-filled layer includes a ferromagnetic substance in the form selected from the group consisting of glass-coated microwires, metal ribbons and powder particles.

76. The method for suppressing electromagnetic interference in functional currents as in claim 75 wherein said ferromagnetic substance is selected from the group consisting of an amorphous metallic alloy, a microcrystalline alloy and a nano-crystalline alloy.

77. The method for suppressing electromagnetic interference in functional currents as in claim 75 wherein said ferromagnetic substance includes chemical elements selected from the group consisting of Co, Si, B, Fe, Ni, Cr, Mn and combinations thereof.

78. The method for suppressing electromagnetic interference in functional currents as in claim 75 wherein said glass-coated microwires having their longitudinal axis pointing toward the same direction.

79. The method for suppressing electromagnetic interference in functional currents as in claim 75 wherein said same direction has an inclination with respect to a segment of said at least one electrical conductor.

80. The method for suppressing electromagnetic interference in functional currents as in claim 75 wherein
(i) said glass-coated microwires have a diameter of between about 0.5 micrometers and about 100 micrometers;
(ii) said metallic ribbons have a thickness of between about 2 micrometers and about 50 micrometers, and
(iii) said powder particles have a diameter in the range of about several nanometers to about several micrometers.

81. The method for suppressing electromagnetic interference in functional currents as in claim 75 wherein said ferromagnetic substance has a relative real permeability of at least 10²

82. The method for suppressing electromagnetic interference in functional currents as in claim 75 wherein said ferromagnetic substance has a relative imaginary permeability of at least 1.

83. The method for suppressing electromagnetic interference in functional currents as in claim 75 wherein said ferromagnetic substance is effected by a magnetic field intensity of at least about 0.02 Oe.

84. The method for suppressing electromagnetic interference in functional currents as in claim 70 wherein said at least one magnetic material-filled layer is selected from the group consisting of a fabric layer and a reinforced layer.

85. The method for suppressing electromagnetic interference in functional currents as in claim 84 wherein said fabric layer is selected from the group consisting of a woven fabric and a non-woven fabric.

86. The method for suppressing electromagnetic interference in functional currents as in claim 84 wherein said reinforced layer includes a reinforcing material selected from the group consisting of a glass fiber, an inorganic filler, a polymeric material and a combination thereof.

87. The method for suppressing electromagnetic interference in functional currents as in claim 70 having two electrical conductors carrying said functional current in a differential mode.

88. The method for suppressing electromagnetic interference in functional currents as in claim 87 wherein a spacing between said two electrical conductors is between about 2 mil. and about 100 mil.

89. The method for suppressing electromagnetic interference in functional currents as in claim 70 wherein a thickness of said magnetic-filled layer is between about 1 mil and about 50 mil.

90. The method for suppressing electromagnetic interference in functional currents as in claim 71 wherein a thickness of said circuit laminate is between about 1 mil. and about 50 mil.

91. The method for suppressing electromagnetic interference in functional currents as in claim 70 wherein a width of said at least one electrical conductor is between about 0.2 mil and about 100 mil.

92. The method for suppressing electromagnetic interference in functional currents as in claim 70 wherein said at least one electrical conductor is connected to a trace conductor in a customer PCB.

93. The method for suppressing electromagnetic interference in functional currents as in claim 92 wherein said connection is via at least one connector on said customer PCB.

94. The method for suppressing electromagnetic interference in functional currents as in claim 92 wherein said customer PCB is used as a part of a larger PCB.

95. The method for suppressing electromagnetic interference in functional currents as in claim 92 wherein said customer PCB is used in electronic equipment.

96. The method for suppressing electromagnetic interference in functional currents as in claim 69 wherein said at least one conductor is attached to a pin of an electrical connector.

97. The method for suppressing electromagnetic interference in functional currents as in claim 69 wherein said at least one conductor is connected in series to a conductor of a common mode toroidal magnetic choke.
